(19) United States
(12) Patent Application Publication
(10) Pub. No.: US 2025/0265381 A1
(43) Pub. Date: Aug. 21, 2025

(54) HARMONIC BALANCE CO-SIMULATION ALGORITHM

(71) Applicant: Kabushiki Kaisha Toshiba, Tokyo (JP)

(72) Inventor: Gavin WATKINS, Bristol (GB)

(73) Assignee: Kabushiki Kaisha Toshiba, Tokyo (JP)

(21) Appl. No.: 18/443,818

(22) Filed: Feb. 16, 2024

(51) Int. Cl. G06F 30/20

(52) U.S. Cl. CPC G06F 30/20

(57) ABSTRACT

A method of co-simulating a system comprising receiving a plurality of time domain sub-simulation results generated by a corresponding plurality of sub-simulations based on a current set of variables, each of the sub-simulations of the plurality of sub-simulations being a sub-simulation of the system, converting each time domain sub-simulation result into the frequency domain to provide a plurality of frequency domain sub-simulation result, determining a harmonic balance cost function of the co-simulation based on the plurality of frequency domain sub-simulation results and updating the current set of variables based on the harmonic balance cost function.

### FIELD

Embodiments described herein relate generally to co-simulation and in particular to a method and system of harmonic balance co-simulation.

### BACKGROUND

Co-simulation allows the simultaneous simulation of multiple systems across a wide range of disciplines (i.e. circuit, electromagnetic, thermal, mechanical, chemical). It is increasingly becoming important in electric vehicles, which embody a range of diverse subsystems.

In the following, embodiments will be described with reference to the drawings in which:

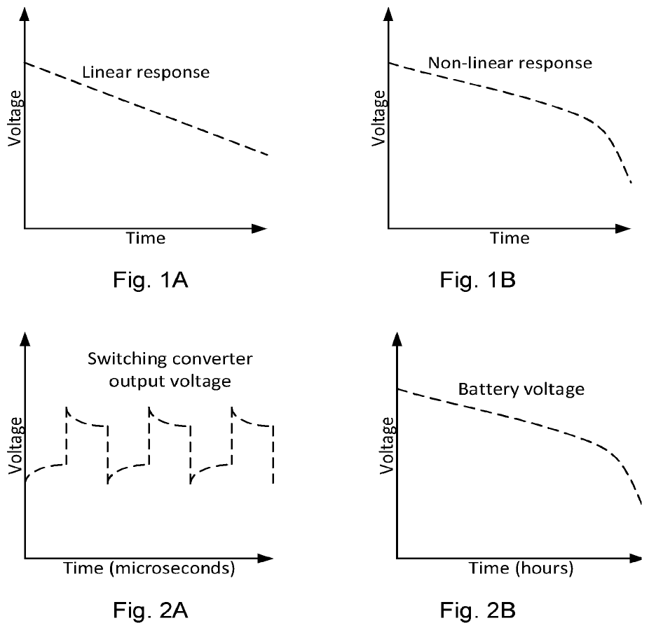

FIG. 1A shows a linear response of a battery;

FIG. 1B shows a non-linear response of a battery;

FIG. 2A shows the simulation of a response of the power converter;

FIG. 2B shows the simulation of a non-linear response of a battery;

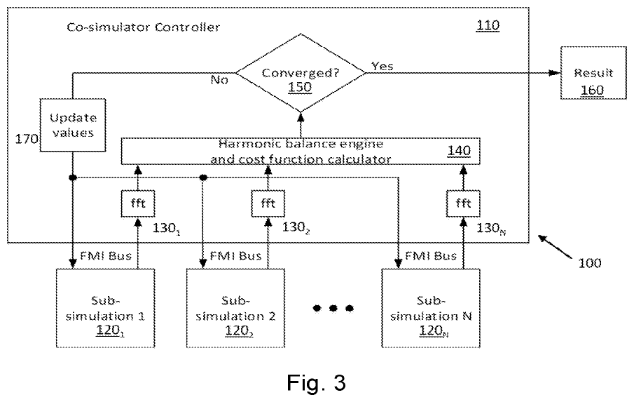

FIG. 3 shows a co-simulation system according to an embodiment;

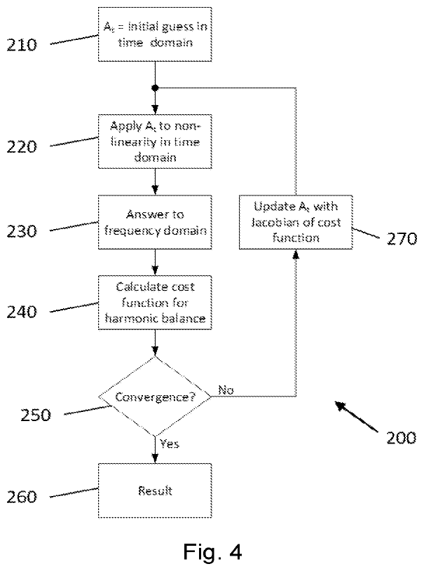

FIG. 4 shows a co-simulation method according to an embodiment;

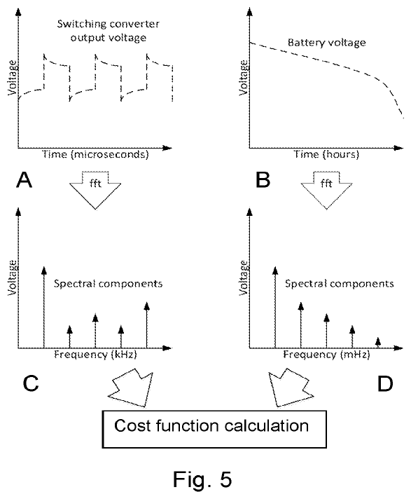

FIG. 5 shows a co-simulation method according to another embodiment;

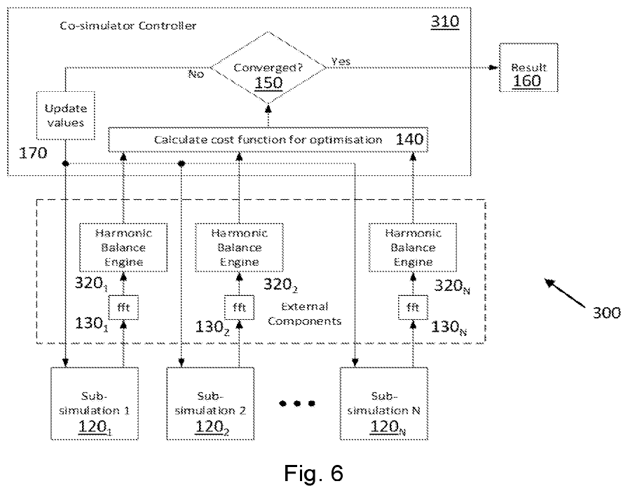

FIG. 6 shows a co-simulation system according to another embodiment;

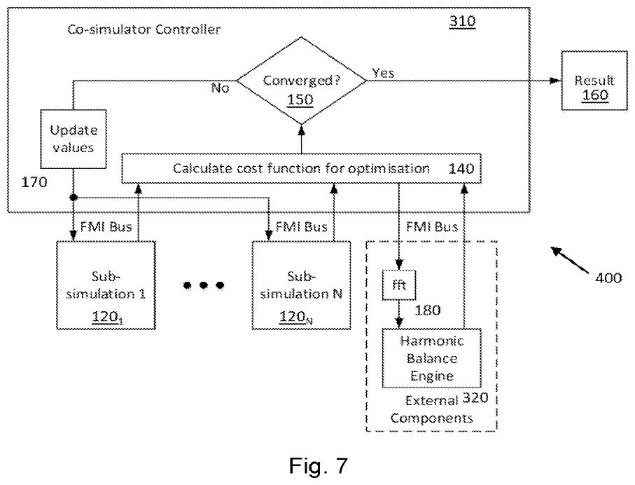

FIG. 7 shows a co-simulation system according to another embodiment.

### DETAILED DESCRIPTION

According to an embodiment there is provided a method of co-simulating a system comprising:
a) receive time domain sub-simulation results generated by a corresponding plurality of sub-simulations based on a current set of variables, each of the sub-simulations of the plurality of sub-simulations being a sub-simulation of the system;
b) converting each time domain sub-simulation result into the frequency domain to provide a plurality of frequency domain sub-simulation result;
c) determining a harmonic balance cost function of the co-simulation based on the plurality of frequency domain sub-simulation results;
d) updating the current set of variables based on the harmonic balance cost function.

An embodiment further comprises for each of the frequency domain sub-simulation results, providing only a subset of the frequency domain sub-simulation result to a cost function calculator, wherein the sub-set comprises frequency domain sub-simulation only at a plurality of predetermined frequencies; and wherein determining the harmonic balance cost function of the co-simulation takes only frequencies that form part of the sub-sets into account.

In an embodiment the pluralities of predetermined frequencies are different for different sub-simulations.

In an embodiment the pluralities of predetermined frequencies for each sub-simulation are harmonics of one or more input frequencies used by the respective sub-simulation.

In an embodiment each of the plurality of sub-simulations is performed by a respective sub-simulator and wherein a FFT converter is associated with each sub-simulator.

In an embodiment each of the plurality of sub-simulations is performed by a respective sub-simulator and wherein an individual frequency selector for providing only the subset of the frequency domain sub-simulation result is associated with each sub-simulator.

In an embodiment each of the plurality of sub-simulations is performed by a respective sub-simulator and wherein a single frequency selector for providing only the subset of the frequency domain sub-simulation result is associated with the plurality of sub-simulators.

An embodiment further comprises, determining whether the cost function has converged and, repeating at least steps a), b) and c) upon determination that the cost function has not converged.

In an embodiment it is determined that the cost function has converged if a change in the cost function when compared to an immediately previous value of the cost function is below a predetermined threshold.

According to another embodiment there is provided a co-simulating system for simulating a technical system, the co-simulation system comprising:
a plurality of sub-simulators configured to perform a plurality of sub-simulations based on a current set of variables, each of the sub-simulations of the plurality of sub-simulations being a sub-simulation of the technical system and each of the sub-simulations of the plurality of sub-simulations providing a time domain sub-simulation result;
one or more converters configured to convert each time domain sub-simulation result into the frequency domain to provide a plurality of frequency domain sub-simulation result;
a harmonic balance engine and a cost function calculator configured to jointly determine a harmonic balance cost function of the co-simulation based on the plurality of frequency domain sub-simulation results; and
an udating module configured to update the current set of variables based on the harmonic balance cost function.

According to another embodiment there is provided a computer program product for execution by one or more processors, the computer program product configured to cause the one or more processors, when executed thereon, to perform a method of co-simulating a system, the method comprising:
receive time domain sub-simulation results generated by a corresponding plurality of sub-simulations based on a current set of variables, each of the sub-simulations of the plurality of sub-simulations being a sub-simulation of the system;
converting each time domain sub-simulation result into the frequency domain to provide a plurality of frequency domain sub-simulation result;
determining a harmonic balance cost function of the co-simulation based on the plurality of frequency domain sub-simulation results;
updating the current set of variables based on the harmonic balance cost function.

Co-simulation algorithms deal with the coupling of these different sub-simulations and their synchronisation in the time domain. Known co-simulation algorithms use co-simulation controllers interfacing with the sub-simulations using the industrial standard Functional Mock-up Interface (FMI) bus.

Real life equivalents of simulated components have non-linear responses. The simplest model would be a linear response as shown in FIG. 1A for a battery where the output voltage drops linearly during discharge. This could be a simple Thevenin model consisting of a voltage source and fixed output resistance. Capacitors are often included to model the short-term dynamic response. Practically, the voltage tends to droop with a non-linear response as shown in FIG. 1B. Such a non-linear response cannot be modelled with a fixed resistance. The simulation of non-linear responses causes distortion.

The non-linear discharge of a battery happens over the space of hours, as shown in FIG. 2B. The transient response of the power converter used to transform the battery voltage to that required by the motor in contrast must be simulated with a time step in the microseconds region as shown in FIG. 2A to capture its dynamic response. It was realised that these two widely different time steps are hard to synchronise with known transient simulation leading to insatiability and errors. More generally, the different disciplines involved in the co-simulation of some systems, such as, for example, an electric vehicle, require different time resolutions.

One known sub-simulation optimisation technique is referred to as harmonic balance and is known from, for example, Fabio L. Traversa, Fabrizio Bonani, “Improved Harmonic Balance Implementation of Floquet Analysis for Nonlinear Circuit Simulation”, AEU Int. J. Electron. Communications, 51 (1997) No. 1, 1-1, the entirety of which is incorporated herein by reference, and Hans-Dieter Lang, Xingqi Zhang, “The Harmonic Balance Method”, ECE 1254-MODELING OF MULTIPHYSICS SYSTEMS, Spring 2013, the entirety of which is incorporated herein by reference. Harmonic balance calculates the steady-state response of nonlinear differential equations in the frequency domain. It applies Kirchhof's current law in the frequency domain at the harmonics of interest. When a sine wave is applied to a nonlinear component, harmonics are generated. HB assumes the solution can be represented by a linear combination of harmonically related sine wave. It then balances the currents and voltages to satisfy Kirchhoff's law.

In complex systems like electric vehicles (EV) s with hybrid power trains, different parts of the system can have widely different time steps as shown in FIGS. 2A and 2B. It was recognised that synchronising them in the time domain can be challenging and can lead to instability as a fast sub-simulation with a high time resolution can require a large number of samples to align with a slower sub-simulator. For example, 10⁹ samples may be needed to synchronise a sub-system that operates on an hours scale with a sub-system that operates on a microsecond time scales. Such large amounts of data can be difficult to store and slow to move around a co-simulation system, in particular when sub-simulations are happening in different geographic zones or in the cloud.

It was realised that, by moving the optimisation into the frequency domain, sub-simulations of different time step can be combined with ease. FIG. 3 shows a co-simulation system 100 of an embodiment and FIG. 4 shows a co-simulation method 200 of an embodiment. The co-simulation method 200 may be executed within the co-simulation system 100.

The co-simulation system 100 includes a co-simulation controller 110 and N co-simulation sub-systems 120₁ to 120_{N}. The co-simulation sub-systems 120₁ to 120_{N} may operate in different technical disciplines, such as electrical, mechanical and chemical. It is expected that co-simulation sub-systems 120₁ to 120_{N} simulating electrical sub-systems have a higher frequency of simulation output than co-simulation sub-systems 120₁ to 120_{N} simulating mechanical sub-systems and that co-simulation sub-systems 120₁ to 120_{N} simulating mechanical sub-systems have a higher frequency of simulation output than co-simulation sub-systems 120₁ to 120_{N} simulating chemical sub-systems. In one embodiment the co-simulation sub-systems 120₁ to 120_{N} operate with different time steps. Put in other words, co-simulation sub-systems 120₁ to 120_{N} may not be synchronised by virtue of the nature of the sub-systems they simulate and consequently produce simulation sub-results at different times, depending on the duration of the respective sub-simulations. Coordination of the co-simulation sub-systems is achieved by the co-simulation algorithm through the harmonic balance engine. The difference in the durations of the sub-simulations may be drastic, such as for example, 1:1,000,000. In an embodiment the co-simulation controller 110 coordinates the co-simulation process. The co-simulation controller 110 and co-simulations sub-systems 120₁ to 120_{N} communicate with each other via a FMI bus. The co-simulations sub-systems 120₁ to 120_{N} provide simulation results in the time domain in a known manner. The system 110 comprises Fast Fourier Transform components 130₁ to 130_{N} that transform the simulation results from the time domain into the frequency domain.

The controller 110 comprises or is in communicative contact with a memory that stores computer program instructions that, when executed by the harmonic balance engine and cost function calculator 140 extract the harmonics on which optimisation of the co-simulation is to be based and, on their basis, calculate the cost function of the simulated system using harmonic balance. Specifically and to save calculation bandwidth, the computer program instructions cause the controller 110 to calculate the cost function only for the frequencies selected by the harmonic balance engine and cost function calculator 140. These preselected frequencies are harmonics that occur at N times the input signal frequency, wherein N is a whole number. Focussing on selected frequencies in this manner result in quicker simulation convergence when compared to simulations covering the whole frequency or time domains. It will be appreciated that different sub-systems use different input frequencies. The harmonic balance engine function of the harmonic balance engine and cost function calculator 140 selects all harmonics of all input frequencies of all sub-systems and provides the relevant simulation results at the so selected frequencies to the cost function calculator of the harmonic balance engine and cost function calculator 140 for calculation of the cost function.

In one embodiment the input frequencies applied by the co-simulation sub-systems 120₁ to 120_{N} are communicated to the harmonic balance engine and cost function calculator 140 by the co-simulation sub-systems 120₁ to 120_{N}, thereby enabling the harmonic balance engine and cost function calculator 140 to extract the harmonics of the input frequencies from the spectral information provided by the FFT components 130₁ to 130_{N}. As different sub-systems simulated by the different co-simulation sub-systems 120₁ to 120_{N} have different input frequencies, the extracted harmonic content differs between the spectra provided by the different FFT components 130₁ to 130_{N}.

Input frequencies may be any frequencies that are applied within the entire simulated system, either across a number of the simulated sub-systems or that are specific to only one simulated sub-system. In an electric vehicle input frequencies used in sub-simulators may include the frequency of the current applied to electric motors and the frequency at which a spring in the suspension of the car bounces. Other examples include resonant frequencies that occur in aircraft. For example, where different parts of an aircraft body (wings, landing gear, tail) have different resonating frequencies. Mechanical systems, such as the engine, will have a characteristic frequencies, for example based on engine rotation. Pumps, such as fuel pumps also operate at a certain frequency.

In one embodiment the input frequencies used by a single co-simulation sub-systems 120₁ to 120_{N} may change between different simulation steps undertaken by the co-simulation sub-systems 120₁ to 120_{N}. This can, for example, be the case, where different load scenarios for an electric engine driving an electric vehicle are simulated in different simulation steps/iterations. In some electric vehicles the rotational speed of an electric motor is changed by changing the frequency of a drive voltage applied to the electric motor, so that, for different vehicle speeds, different electric motor driving frequencies need to be considered/simulated.

FIGS. 5A and 5B illustrate the time domain outputs generated by two of the sub-simulators 120₁ to 120_{N}. Following their transformation into the frequency domain using the relevant ones of the FFT components 130₁ to 130_{N}, as shown in FIGS. 5D and 5D (with low frequency (DC) components already removed), the dominant frequency components are extracted from the signals spectra by the harmonic balance engine function of the harmonic balance engine and cost function calculator 140 and provided to the cost function calculator function of the harmonic balance engine and cost function calculator 140.

With reference to FIG. 3, the controller 110 implements a module 150 for determining, based on the cost function, if the simulation has converged. If the simulation is deemed to have converged by module 150, a simulation result is output at the output 160 of the controller 110. If the simulation has not yet converged, the controller 110 determines an update to variable At of functions that describes the behaviour of the system 100and returns the update to variables At to the relevant sub-simulation units 120₁ to 120_{N} for a future iteration of their local simulation process.

As shown in FIG. 4, a co-simulation process 200 of an embodiment is initiated 210 with an initial estimate of variables At. In an embodiment the initial estimates are provided by the relevant sub-simulation components 120₁ to 120_{N}. In step 220 the sub-simulation components 120₁ to 120_{N} simulate the behaviour of their relevant sub-system based on the current estimate of variables At in the time domain. In step 230, the Fourier Transform components 130₁ to 130_{N} transform time domain response signals generated by the sub-simulation components 120₁ to 120_{N} into the frequency domain for extraction of the relevant frequencies by the harmonic balance engine component of the harmonic balance engine and cost function calculator 140 and for calculation of the cost function by the cost function calculator component of the harmonic balance engine and cost function calculator 140 in step 240. As discussed above, the cost function is evaluated only for the above mentioned predetermined set of frequencies. Given that the sub-simulation components 120₁ to 120_{N} may be operated independently from the controller 110, the sub-simulations results provided to the controller may describe the behaviour of the respective sub-system across a spectrum of frequencies. Nevertheless, the controller 110 limits its operation to the predetermined set of frequencies described above.

In step 250 the cost function is evaluated to determine if the simulation has converged. If it is determined in this step that the simulation has converged (for example because a change in the cost function between co-simulation steps is smaller than a threshold change), then the current values of the variable At are output in step 270.

If further simulation iterations are required before convergence criteria are met, then the values of variables At as used in the preceding simulation step by sub-simulation components 120₁ to 120_{N} are modified by the Jacobian of the calculated cost-function in step 270 by component 170 of the controller 110 and provided to the sub-simulation components 120₁ to 120_{N}.

The system 100 described with reference to FIG. 3 comprised a controller 110 that could be modified by adding the FFT components 130₁ to 130_{N} and the function of the harmonic balance engine. Not all co-simulation controller may be modifiable in this manner. FIG. 6 illustrates a system 300 in which the co-simulation controller 310 does not require modification by addition of the FFT components 130₁ to 130_{N} or the functions of the harmonic balance engine. Instead, the FFT components 130₁ to 130_{N} and individual harmonic balance engines 320₁ to 320_{N} are added on the sub-simulator side of the FMI bus and interface to the FMI bus. The harmonic balance engines 320₁ to 320_{N} isolate the harmonic frequencies upon which the simulation is to focus from other frequency information provided by the FFT components 130₁ to 130_{N}.

FIG. 7 shows another co-simulation algorithm according to another embodiment. As can be seen from the figure, the co-simulation controller 310 remains un-modified when compared to known co-simulation controllers. However, similar to the embodiment shown in FIG. 6, FFT component 180 and harmonic balance engine 320 are provided external to the co-simulation controller 310. In contrast to the embodiment shown in FIG. 6, however, only a single FFT component 180 and a single harmonic balance engine 320 are provided or indeed required. This is because the FFT component 180 sequentially receives the simulation outputs of the sub-simulation components 120₁ to 120_{N} either, as shown in FIG. 7, directly from component 140 or, via the FMI bus or a separate bus, from sub-simulation components 120₁ to 120_{N} and delivers the frequency domain version of the respective simulation outputs to the harmonic balance engine 320. The harmonic balance engine 320 in turn sequentially provides the selected frequencies to the cost function calculation component 140.

Whilst certain embodiments have been described, these embodiments have been presented by way of example only, and are not intended to limit the scope of the inventions. Indeed, the novel devices, and methods described herein may be embodied in a variety of other forms; furthermore, various omissions, substitutions and changes in the form of the devices, methods and products described herein may be made without departing from the spirit of the inventions. The accompanying claims and their equivalents are intended to cover such forms or modifications as would fall within the scope and spirit of the inventions.

1. A method of co-simulating a system comprising:
a) receiveing time domain sub-simulation results generated by a corresponding plurality of sub-simulations based on a current set of variables, each of the sub-simulations of the plurality of sub-simulations being a sub-simulation of the system;
b) converting each time domain sub-simulation result into the frequency domain to provide a plurality of frequency domain sub-simulation result;
c) determining a harmonic balance cost function of the co-simulation based on the plurality of frequency domain sub-simulation results;
d) updating the current set of variables based on the harmonic balance cost function.

2. The method of claim 1, further comprising for each of the frequency domain sub-simulation results, providing only a subset of the frequency domain sub-simulation result to a cost function calculator, wherein the sub-set comprises frequency domain sub-simulation only at a plurality of predetermined frequencies; and
wherein determining the harmonic balance cost function of the co-simulation takes only frequencies that form part of the sub-sets into account.

3. The method of claim 2, wherein the pluralities of predetermined frequencies are different for different sub-simulations.

4. The method of claim 3, wherein the pluralities of predetermined frequencies for each sub-simulation are harmonics of one or more input frequencies used by the respective sub-simulation.

5. The method of claim 1, wherein each of the plurality of sub-simulations is performed by a respective sub-simulator and wherein a FFT converter is associated with each sub-simulator.

6. The method of claim 2, wherein each of the plurality of sub-simulations is performed by a respective sub-simulator and wherein an individual frequency selector for providing only the subset of the frequency domain sub-simulation result is associated with each sub-simulator.

7. The method of claim 2, wherein each of the plurality of sub-simulations is performed by a respective sub-simulator and wherein a single frequency selector for providing only the subset of the frequency domain sub-simulation result is associated with the plurality of sub-simulators.

8. The method of claim 1, further comprising, determining whether the cost function has converged and, repeating at least steps a), b) and c) upon determination that the cost function has not converged.

9. A co-simulating system for simulating a technical system, the co-simulation system comprising:
a plurality of sub-simulators configured to perform a plurality of sub-simulations based on a current set of variables, each of the sub-simulations of the plurality of sub-simulations being a sub-simulation of the technical system and each of the sub-simulations of the plurality of sub-simulations providing a time domain sub-simulation result;
one or more converters configured to convert each time domain sub-simulation result into the frequency domain to provide a plurality of frequency domain sub-simulation result;
a harmonic balance engine and a cost function calculator configured to jointly determine a harmonic balance cost function of the co-simulation based on the plurality of frequency domain sub-simulation results; and
an udating module configured to update the current set of variables based on the harmonic balance cost function.

10. The co-simulating system of claim 9, wherein the harmonic balance engine is configured to, for each of the frequency domain sub-simulation results, provide only a subset of the frequency domain sub-simulation result to the cost function calculator, wherein the sub-set comprises frequency domain sub-simulation only at a plurality of predetermined frequencies; and
wherein the cost function calculator is configured to determine the harmonic balance cost function of the co-simulation by taking only frequencies that form part of the sub-sets into account.

11. The co-simulating system of claim 10, wherein the pluralities of predetermined frequencies are different for different sub-simulations.

12. The co-simulating system of claim 11, wherein the pluralities of predetermined frequencies for each sub-simulation are harmonics of one or more input frequencies used by the respective sub-simulation.

13. The co-simulating system of claim 9, wherein each of the plurality of sub-simulations is performed by a respective sub-simulator and wherein a FFT converter is associated with each sub-simulator.

14. The co-simulating system of claim 10, wherein each of the plurality of sub-simulations is performed by a respective sub-simulator and wherein an individual convertor for providing only the subset of the frequency domain sub-simulation result is associated with each sub-simulator.

15. The co-simulating system of claim 10, wherein each of the plurality of sub-simulations is performed by a respective sub-simulator and wherein a single frequency selector for providing only the subset of the frequency domain sub-simulation result is associated with the plurality of sub-simulators.

16. The co-simulating system of claim 1, further comprising a decider for determining whether the cost function has converged and initiating a further sub-simulation iteration upon determination that the cost function has not converged.

17. A computer program product for execution by one or more processors, the computer program product configured to cause the one or more processors, when executed thereon, to perform a method of co-simulating a system, the method comprising:
receive time domain sub-simulation results generated by a corresponding plurality of sub-simulations based on a current set of variables, each of the sub-simulations of the plurality of sub-simulations being a sub-simulation of the system;
converting each time domain sub-simulation result into the frequency domain to provide a plurality of frequency domain sub-simulation result;
determining a harmonic balance cost function of the co-simulation based on the plurality of frequency domain sub-simulation results;
updating the current set of variables based on the harmonic balance cost function.

18. The computer program product of claim 17, the computer program product further configured to cause the one or more processor to, for each of the frequency domain sub-simulation results, provide only a subset of the frequency domain sub-simulation result to a cost function calculator, wherein the sub-set comprises frequency domain sub-simulation only at a plurality of predetermined frequencies; and
wherein determining the harmonic balance cost function of the co-simulation takes only frequencies that form part of the sub-sets into account.

19. The computer program product of claim 18, wherein the pluralities of predetermined frequencies are different for different sub-simulations.

20. The computer program product of claim 18, wherein the pluralities of predetermined frequencies for each sub-simulation are harmonics of one or more input frequencies used by the respective sub-simulation.
